(19) United States
(12) Patent Application Publication
(10) Pub. No.: US 2012/0133039 A1
(43) Pub. Date: May 31, 2012

(54) SEMICONDUCTOR PACKAGE WITH THERMAL VIA AND METHOD OF FABRICATION

(75) Inventors: Julien Pruvost, Le-Pont-de-Claix (FR); Jerome Lopez, Saint-Joseph-de-Riviere (FR); Jean-Michel Riviere, Froges (FR)

(73) Assignee: STMICROELECTRONICS (GRENOBLE 2) SAS, Grenoble (FR)

(21) Appl. No.: 13/299,531

(22) Filed: Nov. 18, 2011

(30) Foreign Application Priority Data
Nov. 29, 2010 (FR) 1059833

(51) Int. Cl. H01L 23/34; H01L 21/56

(52) U.S. Cl. 257/706; 438/122; 257/E23.08; 257/E21.502

(57) ABSTRACT

A semiconductor package includes a block for encapsulating a microchip and its electrical connection wires. The encapsulating block has at least one front recess disposed on top of the microchip. A thermally conducting filling material fills the front recess so as to form a thermal via. A radiating structure is attached over the encapsulating block and in thermal communication with the thermal via.

### PRIORITY CLAIM

This application claims priority from French Application for Patent No. 1059833 filed Nov. 29, 2010, the disclosure of which is hereby incorporated by reference.

### TECHNICAL FIELD

The present invention relates to the field of semiconductor packages.

### BACKGROUND

Semiconductor packages are known that comprise a support plate for electrical connection, at least one integrated circuit microchip having, on a front face, integrated circuits and, on its periphery, front bump contacts for electrical connection and a back face of which is fixed onto a front face of the support plate, electrical connection wires connected to the front bump contacts of the chip and to front bump contacts of the support plate, and an encapsulation block on the front face of the support plate, in which the microchip and the electrical connection wires are embedded.

For the purpose of evacuating the heat produced by the microchip, such known packages can be equipped with a metal plate placed on the encapsulation block and whose peripheral edge is embedded in the encapsulation block and which can be equipped with a metal radiator bonded onto the metal plate.

Nevertheless, it turns out that the performance of such a disposition is unsatisfactory in the case where the quantity of heat to be evacuated is significant.

### SUMMARY

A semiconductor package is provided that comprises a support plate for electrical connection; at least one integrated circuit microchip having, on a front face, integrated circuits and, on its periphery, front electrical connection bump contacts and a back face of which is fixed onto a front face of the support plate; electrical connection wires connected to the front bump contacts of the microchip and to front bump contacts of the support plate; an encapsulation block on the front face of the support plate and in which the microchip and the electrical connection wires are embedded; at least one front recess disposed on top of the microchip and comprising at least one hole formed in the encapsulation block in at least one area free of wires or of electrical connection bump contacts; and a thermally conducting filling material, filling the said front recess, in such a manner as to form a thermal via.

The thermally conducting filling material can exhibit a thermal transfer coefficient greater than that of the material forming the encapsulation block.

The package can comprise a metal plate having at least one part extending over the encapsulation block, the said front recess comprising at least one opening disposed through this metal plate.

The package can comprise a radiator fixed on top of the encapsulation block and passing in front of the said recess, this radiator being thermally connected to the filling material of this recess.

The radiator can be fixed onto the encapsulation block by means of a layer of a thermally conducting material, this layer extending over the filling material of the said recess.

The radiator can be fixed onto the encapsulation block by means of a layer of a thermally conducting material, this layer filling the said recess.

A method is also provided for fabrication of a semiconductor package equipped with a radiator, comprising: form at least one front recess in an encapsulation block on top of at least one integrated circuit microchip, in at least one area free of wires or of electrical connection bump contacts; fill the said recess with a thermally conducting material; and fix the radiator onto the encapsulation block by means of a layer of a thermally conducting material extending over the thermally conducting material filling the said recess.

A method is also provided for fabrication of a semiconductor package equipped with a radiator, comprising: form at least one front recess in the encapsulation block on top of at least one integrated circuit microchip, in at least one area free of wires or of electrical connection bump contacts; and fix the radiator onto the encapsulation block by means of a layer of a thermally conducting material, this thermally conducting material filling the said recess.

The radiator can be fixed onto the encapsulation block by means of a metal plate, the said recess comprising at least one opening disposed through this metal plate.

### BRIEF DESCRIPTION OF THE DRAWINGS

Semiconductor packages will now be described by way of non-limiting examples, illustrated by the appended drawing in which:

FIG. 1 shows a cross-section of a semiconductor package, and

FIG. 2 shows a cross-section of another semiconductor package.

### DETAILED DESCRIPTION OF THE DRAWINGS

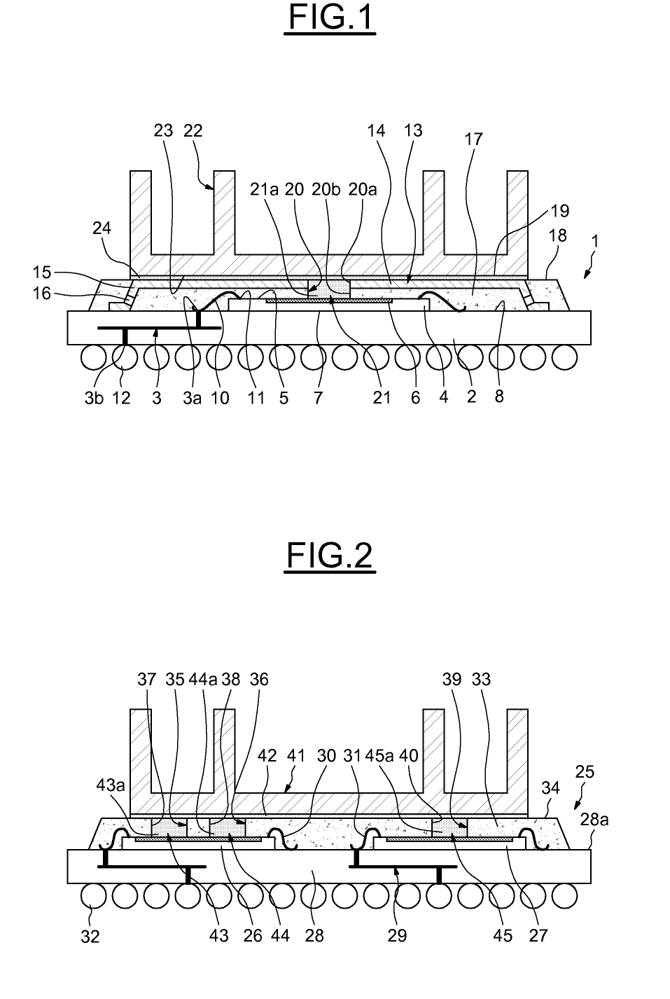

As illustrated in FIG. 1, a semiconductor package 1 comprises a support plate 2 for electrical connection including an integrated electrical interconnection network 3, an integrated circuit microchip 4 having, in a front face 5, integrated circuits 6 and a back face 7 of which is fixed onto a central part of a front face 8 of the support plate 2 by means of a layer of adhesive and/or of beads or of electrical interconnection pillars. Electrical connection wires 10 connect front bump contacts 11 of the microchip 3, disposed on the periphery of its front face 5, and front bump contacts 3a of the electrical interconnection network 3 of the support plate 2, disposed on its front face 8. On the back face of the support plate 2 are disposed, in particular, beads for external electrical connection 12 placed on backside bump contacts 3b of the interconnection network 3 of the support plate 2.

The semiconductor package 1 also comprises a metal plate 13, for example made of copper covered with nickel, which has a central part 14 running above and at a distance from the microchip 4, and connection wires 10, parallel to the front face 8 of the support plate 2, and which has one or more edge lips 15 bent down towards the front face 8 of the support plate 2 and resting on this front face 8, the edge lips 15 being disposed in such a manner as to leave access openings 16.

The semiconductor package 1 furthermore comprises an encapsulation block 17, made from a material such as for example an epoxy resin injected into a mold, formed on the front face 8 of the support plate 2 and in which the microchip 4, the electrical connection wires 10 and the edge lips 15 of the metal plate 13 are embedded, the material being able to flow through the access passages 16 of the metal plate 13 during the injection so as to fill this plate. The encapsulation block 17 then presents a front face 18 parallel to the front face 8 of the support plate 2 and in the plane of the front face 19 of the metal plate 13.

The semiconductor package 1 has at least one recess 20 which is situated on top of the microchip 4 and which is formed by an opening 20a disposed through the central part 14 of the metal plate 13 and by a hole 20b formed in the encapsulation block 17 either as far as the front face 5 of the microchip 4 or up to a short distance from this front face 5, leaving a remaining thin layer of the material of the encapsulation block 17.

The recess 20 is filled with a thermally conducting material 21a in such a manner as to form a front thermal via 21. This thermally conducting material 21a has a thermal capacity or transfer coefficient greater, or even much greater, than the thermal capacity or transfer coefficient of the material forming the encapsulation block 17.

The thermally conducting material 21a forming the front thermal via 21 can be a thermal paste or a loaded polymer, which could be a phase-change material.

The semiconductor package 1 is equipped with a radiator 22 which has a flat back face 23 fixed onto the metal plate 13 and potentially onto the flat front face 18 of the encapsulation block 17 by means of a layer of thermally conducting adhesive 24, in such a manner that the back face 23 of the radiator 22 runs in front of the recess 20 and that the layer of thermally conducting adhesive 24 is in contact with or linked to the thermally conducting material 21 filling the recess 20.

The result of the above is that the heat produced by the microchip 4 can be at least partly evacuated towards the front by the radiator 22 preferably by means of the thermally conducting material 21 filling the recess 20 and additionally through the encapsulation block 17, which is more or less a thermal insulator, and through the metal plate 13. The metal plate 13 and the layer of thermally conducting adhesive 24 contribute to a surface distribution of the heat with respect to the back face 23 of the radiator 22.

According to one variant embodiment, the passage 20a through the metal plate 13 can be formed before it is mounted, then the hole 20b can be formed in the encapsulation block 17 through the passage 20a in the installed metal plate 13.

According to another variant embodiment, the encapsulation block can be equipped with a full metal plate 13, then the passage 20a can be formed through the metal plate, for example by mechanical drilling by means of a tool, and the hole 20b in the encapsulation block 17 can be made through this passage 20a formed in situ.

The hole 20a can be made by laser drilling or mechanically by a tool, without however touching the front face 5 of the microchip 4 so as not to damage its integrated circuits 6.

According to one variant embodiment, the recess 20 can be filled by the thermal filling material 21, then the radiator 22 can be fixed by means of the layer of thermal adhesive 24. The thermal filling material 21 can be a thermal paste or a polymer loaded with thermal particles, applied for example by means of a syringe and, where necessary, hardened after its application.

According to another variant embodiment, the radiator 22 can be directly fixed by means of the layer of thermal adhesive 24, this layer of thermal adhesive 24 being designed to simultaneously fill the recess 20.

In any of the above cases, the layer of thermally conducting adhesive 24 can be a thermal paste or a loaded polymer, which could be a phase-change material. Furthermore, a metal grid can be included in this layer of adhesive 24.

As illustrated in FIG. 2, a semiconductor package 25 differs from that described with reference to FIG. 1 by the fact that it comprises at least two integrated circuit microchips 26 and 27, whose back faces are fixed onto a front face 28a of a support plate 28 including an electrical interconnection network 29. Electrical connection wires 30 and 31 respectively connect front bump contacts of the microchips 26 and 27 and front electrical connection bump contacts of the support plate 28 and external electrical connection beads 32 are placed on backside electrical connection bump contacts of the support plate 28.

As a comparison, the semiconductor package 25 does not comprise the metal plate 13 of the semiconductor package 1. The semiconductor package 25 comprises an encapsulation block 33 formed on the front face 28a of the support plate 28 and in which the microchips 26 and 27 and the electrical connection wires 30 and 31 are embedded, in such a manner that the encapsulation block 33 has a front face 34 parallel to the front face 28a of the support plate 28.

As a further comparison, the encapsulation block 33 has at least two recesses 35 and 36 disposed on top of the microchip 26 in the form of holes 37 and 38 and at least one recess 39 disposed on top of the microchip 27 in the form of a hole 40.

As in the preceding example, the semiconductor package 25 is equipped with a radiator 41, which this time is fixed directly onto the front face 34 of the encapsulation block 33 by means of a layer of thermal adhesive 42.

As in the preceding example, the recesses 35, 36 and 39 can, prior to the mounting of the radiator 41, be filled with a thermal filling material 43a, 44a and 45a, forming thermal vias 43, 44 and 45, or can be filled by the layer of thermal adhesive 42 during the installation of the radiator 41 so as to form these thermal vias.

The present invention is not limited to the examples described hereinabove. Many other variant embodiments and variations in combination of the dispositions described are possible, without straying from the scope of the invention defined by the appended claims.

What is claimed is:

1. A semiconductor package, comprising:
a support plate for electrical connection;
at least one integrated circuit microchip having, on a front face, integrated circuits and, on its periphery, front bump contacts for electrical connection and a back face of which is fixed onto a front face of the support plate;
electrical connection wires connected to the front bump contacts of the microchip and to front bump contacts of the support plate;
an encapsulation block on the front face of the support plate and in which the microchip and the electrical connection wires are embedded,
at least one front recess disposed on top of the microchip and comprising at least one hole formed in the encapsulation block in at least one area free of electrical connection wires or electrical connection bump contacts; and
a thermally conducting filling material filling said front recess in such a manner as to form a thermal via.

2. The package according to claim 1, wherein the thermally conducting filling material is one of a thermal paste or a loaded polymer that exhibits a thermal transfer coefficient greater than a thermal transfer coefficient of the material forming the encapsulation block.

3. The package according to claim 2, further comprising a metal plate having at least one part extending over the encapsulation block, and wherein the front recess further comprises at least one opening disposed through said metal plate.

4. The package according to claim 3, wherein the at least one opening disposed through said metal plate is aligned with said at least one hole formed in the encapsulation block.

5. The package according to claim 3, further comprising a radiator attached to a top surface of the metal plate and passing over said front recess, said radiator being thermally connected to the thermally conducting filling material filling said front recess.

6. The package according to claim 5, wherein said radiator is attached to the top surface of the metal plate by a layer of a thermally conducting material, said layer of thermally conducting material extending over the thermally conducting filling material filling said front recess.

7. The package according to claim 5, wherein said radiator is attached to the top surface of the metal plate by said thermally conducting filling material which also fills said front recess.

8. The package according to claim 2, further comprising a radiator attached to a top surface of the encapsulation block and passing over said front recess, said radiator being thermally connected to the thermally conducting filling material filling said front recess.

9. The package according to claim 8, wherein said radiator is attached to the top surface of the encapsulation block by a layer of a thermally conducting material, said layer of thermally conducting material extending over the thermally conducting filling material filling said front recess.

10. The package according to claim 8, wherein said radiator is attached to the top surface of the encapsulation block by said thermally conducting filling material which also fills said front recess.

11. A method for fabricating a semiconductor package, comprising:
attaching a back face of at least one integrated circuit microchip to a front face of a support plate, said integrated circuit microchip having, on a front face, integrated circuits and, on a periphery, front bump contacts for electrical connection;
electrically connecting said front bump contacts of said integrated circuit microchip to front bump contacts of the support plate with connection wires;
embedding the encapsulating integrated circuit microchip and connection wires with an encapsulation block;
forming at least one front recess in the encapsulation block on top of the integrated circuit microchip, in at least one area free of connection wires or front bump contacts for the integrated circuit microchip; and
filling said front recess with a thermally conducting material in such a manner as to form a thermal via.

12. The method according to claim 11, wherein the thermally conducting filling material is one of a thermal paste or a loaded polymer that exhibits a thermal transfer coefficient greater than a thermal transfer coefficient of the material forming the encapsulation block.

13. The method according to claim 12, further comprising, prior to embedding the encapsulating integrated circuit microchip and connection wires with the encapsulation block, attaching a metal plate having at least one part extending over the encapsulation block with at least one opening disposed through said metal plate.

14. The method according to claim 13, wherein the at least one opening disposed through said metal plate is aligned with said at least one front recess in the encapsulation block.

15. The method according to claim 13, further comprising attaching a radiator to a top surface of the metal plate and passing over said front recess, said radiator being thermally connected to the thermally conducting filling material filling said front recess.

16. The method according to claim 15, wherein attaching comprises attaching said radiator to the top surface of the metal plate by a layer of a thermally conducting material, said layer of thermally conducting material extending over the thermally conducting filling material filling said front recess.

17. The method according to claim 15, wherein attaching comprises attaching said radiator to the top surface of the metal plate by said thermally conducting filling material which also fills said front recess.

18. The method according to claim 12, further comprising attaching a radiator to a top surface of the encapsulation block and passing over said front recess, said radiator being thermally connected to the thermally conducting filling material filling said front recess.

19. The method according to claim 18, wherein attaching comprises attaching said radiator to the top surface of the encapsulation block by a layer of a thermally conducting material, said layer of thermally conducting material extending over the thermally conducting filling material filling said front recess.

20. The method according to claim 18, wherein attaching comprises attaching said radiator to the top surface of the encapsulation block by said thermally conducting filling material which also fills said front recess.

21. A method for fabricating a semiconductor package, comprising:
attaching a back face of at least one integrated circuit microchip to a front face of a support plate, said integrated circuit microchip having, on a front face, integrated circuits and, on a periphery, front bump contacts for electrical connection;
electrically connecting said front bump contacts of said integrated circuit microchip to front bump contacts of the support plate with connection wires;
embedding the encapsulating integrated circuit microchip and connection wires with an encapsulation block;
forming at least one front recess in the encapsulation block on top of the integrated circuit microchip, in at least one area free of connection wires or front bump contacts for the integrated circuit microchip; and
attaching a radiator over the encapsulation block passing over said front recess by use of a layer of a thermally conducting material comprising one of a thermal paste or a loaded polymer which also fills said front recess.

22. The method according to claim 21, wherein the radiator is attached to the encapsulation block through an intermediary metal plate, said metal plate having an opening there through which is coupled to the at least one front recess in the encapsulation block filled with the thermally conducting material.
